(19) United States
(12) Patent Application Publication
(10) Pub. No.: US 2005/0041467 A1
(43) Pub. Date: Feb. 24, 2005

(54) Chalcogenide memory

(75) Inventor: Yi Chou Chen, Hsinchu (TW)

Correspondence Address: MARTINE PENILLA & GENCARELLA, LLP, 710 LAKEWAY DRIVE, SUITE 200, SUNNYVALE, CA, 94085, US

(73) Assignee: MACRONIX INTERNATIONAL CO., LTD.

(21) Appl. No.: 10/948,891

(22) Filed: Sep. 24, 2004

Related U.S. Application Data
(63) Continuation-in-part of application No. 10/464,938, filed on Jun. 18, 2003.

(51) Int. Cl. G11C 11/34

(52) U.S. Cl. 365/184

(57) ABSTRACT

A memory core includes a top electrode, a bottom electrode. The memory core also includes a threshold-switching material disposed between the top electrode and the bottom electrode. The threshold-switching material serves as both a steering and a storage element. The memory cores are stacked to make the memory a 3D memory.

### CROSS-REFERENCE TO RELATED APPLICATIONS

The present application is a continuation-in-part of a co-pending application that is commonly assigned to the assignee of the present invention, which is entitled “Transistor-Free Random Access Memory”, application Ser. No. 10/464,938, filed Jun. 18, 2003 (the “Parent Application”); The benefit of 35 U.S.C. Section 120 is hereby claimed with respect to the Parent Application. The present application is related to U.S. patent application Ser. No. 10/465,120, filed on Jun. 18, 2003 and entitled “Method for Adjusting the Threshold Voltage for a Memory Cell.” The disclosure of this related application is incorporated herein by reference for all purposes.

### BACKGROUND OF THE INVENTION

The present invention relates generally to memory devices and, more particularly, to a memory cell structure not requiring access transistors.

Typical memory cells include a steering element, e.g., one or more transistors, to access each cell. The access transistors, which may also be diodes, provide the word lines access to the bit lines of the memory cell. More specifically, the access transistors act as a pass gate to provide access for the word line to the bit line in order to read and write data to a memory cell. For example, dynamic random access memory (DRAM), flash memory, static random access memory (SRAM), conventional chalcogenide memory, ovonic unified memory (OUM) or phase-change random access memory (PCRAM) require transistor or PN diode as the steering element or addressing element. In the case of a DRAM, the steering element is the transistor and the data is stored in a capacitor. Similarly, in SRAM six transistors are needed. However, high quality silicon is needed to fabricate transistors and this poses problems when fabricating transistors over silicon wafers. Consequently, it is difficult to make three dimensional (3D) memory with transistors over silicon wafers.

Memories using poly-silicon p-n junction as the steering element have been suggested as a possible solution. This approach has several drawbacks. For example, these types of memories are limited to one time programmable memory (OTP). Also, this approach requires high programming voltage and high process temperature. High process temperatures prevent the use of Al and Cu metal lines. For instance, the maximum process temperature for aluminum is 500° C. and the process temperature for copper is in the range from about 400° C. to about 500° C. Aluminum and copper are two metals conventionally used for wiring between layers and excluding these metals makes the wiring between layers difficult. Alternatively, when 3D memories are fabricated by a packaging technology, the bonding alignment between layers becomes challenging. In light of the foregoing, there is a need for a memory cell structure that enables selective access to the core cells without the need for an access transistor.

### SUMMARY OF THE INVENTION

Broadly speaking, the present invention enables the access transistor, which is also referred to as a steering element for accessing a memory core cell, to be eliminated through the use of a threshold-switching material that can be programmed to function as a steering element.

In accordance with one aspect of the invention, a memory core that includes a top electrode and a bottom electrode is provided. The memory core further includes a threshold-switching material disposed between the top electrode and the bottom electrode. The threshold-switching material serves as both a steering and a storage element.

In accordance with another aspect of the present invention, a 3D memory is provided. The 3D memory includes a plurality of array of memory cores. The memory cores comprise a word line a bit line. The memory cores further comprise a threshold-switching material disposed between the word line and the bit line.

In accordance with yet another aspect of the present invention, a method for accessing a memory core in a 3D memory is provided. The method initiates with determining a threshold voltage for access to a memory core. Then, a threshold-switching material of the memory core is programmed to enable access to the memory core at the threshold voltage. Next, a voltage is applied to a word line in communication with the memory core. If the voltage is at least as large as the threshold voltage, then the method includes accessing the memory core.

In accordance with yet another aspect of the present invention, a method for reading a 3D chalcogenide memory device is provided. The method initiates with applying a read voltage to a word line. The read voltage is configured to directly access the chalcogenide memory device. Then, a zero bias is applied on the bit line corresponding to the word line. Next, a value stored in the chalcogenide memory device is read.

It will be apparent to those skilled in the art that the present invention can be applied in numerous memory/solid state device applications. One of the significant advantages of the memory core is the elimination of access transistors that function as steering elements for signals to the memory core cells. Moreover, the programming voltage required by the memory core is low. Also, the process temperature is low. The invention facilitates fabrication of 3D memory and the memory fabricated may be non-volatile and fast.

It is to be understood that the foregoing general description and the following detailed description are exemplary and explanatory only and are not restrictive of the invention, as claimed.

### BRIEF DESCRIPTION OF THE DRAWINGS

The accompanying drawings, which are incorporated in and constitute part of this specification, illustrate exemplary embodiments of the invention and together with the description serve to explain the principles of the invention.

FIG. 1A illustrates a memory core in accordance with an embodiment of the invention.

FIG. 1B illustrates a memory core in accordance with an embodiment of the invention.

FIGS. 2A and 2B illustrate stacking memory cores to fabricate 3D memories.

FIG. 2C illustrates a cross-section of a 3D memory fabricated by stacking memory cores.

FIG. 3A illustrates an array of memory cores forming a layer.

FIG. 3B illustrates an array of memory cores connected to bit line and word line selector circuits.

FIG. 3C illustrates a schematic of a multilayered three-dimensional memory.

FIG. 3D illustrates an array of memory cores forming layers that are part of a 3D memory.

FIGS. 4A through 4D illustrate exemplary plots associated with programming techniques that may be applied to a chalcogenide memory device.

FIGS. 5A through 5C illustrate three exemplary methods for reading a device.

### DETAILED DESCRIPTION OF EXEMPLARY EMBODIMENTS

Several exemplary embodiments of the invention will now be described in detail with reference to the accompanying drawings.

In accordance with the present invention, a threshold-switching material is incorporated into a memory cell in order to eliminate the need for access transistors. In one embodiment, the threshold-switching material is a chalcogenide material. Further information on adjusting the threshold voltage, Vth, of a material capable of changing Vth is discussed in related U.S. patent application Ser. No. 10/465,120.

In one embodiment, the transistor-like properties of the threshold-switching material are exploited to simplify the memory cell structure by enabling the elimination of the steering element, e.g., the access transistor or P-N diode. It will be apparent to one skilled in the art that the chalcogenide memory cell may be embedded with logic circuits to form a system on a chip (SoC). Furthermore, with respect to chalcogenide, the nonvolatile nature, once programmed, enables relatively fast reading and writing operations. It should be appreciated that the programming voltage associated with a threshold-switching material, like a chalcogenide material, is much lower than that of a flash read only memory (ROM). For example, the programming voltage associated with a chalcogenide memory cell is about 5 volts (V) as compared to a programming voltage of about 10 V for a flash ROM.

The chalcogenide memory cell is capable of functioning both as a steering device and a memory device. Accordingly, the fabrication of just a chalcogenide memory cell is much easier than combining both a transistor and a chalcogenide memory cell. Additionally, when the memory cell also acts as a steering device, this enables a reduction in the chip size for the same amount of memory as compared to a memory having separate steering devices and memory cells. Alternatively, a dual functioning chalcogenide memory may be able to provide more memory capacity as compared to similar size memories having separate steering devices and memory cells. As discussed herein, a minimum-sized chalcogenide memory device is capable of passing a higher current as compared to an access transistor. It should be appreciated that while a chalcogenide material is used as an example of a threshold-switching material, the embodiments described herein are not limited to a chalcogenide material. Any suitable material having the desirable characteristics of a chalcogenide material, i.e., having stable and tunable voltage threshold (Vth) properties, may serve as a nonvolatile dual function memory cell.

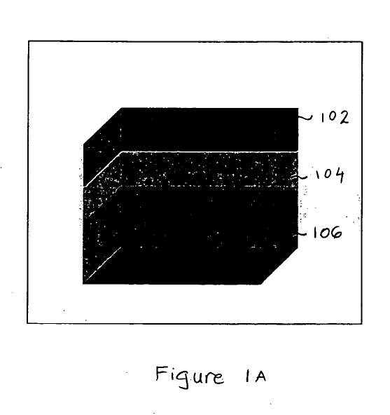

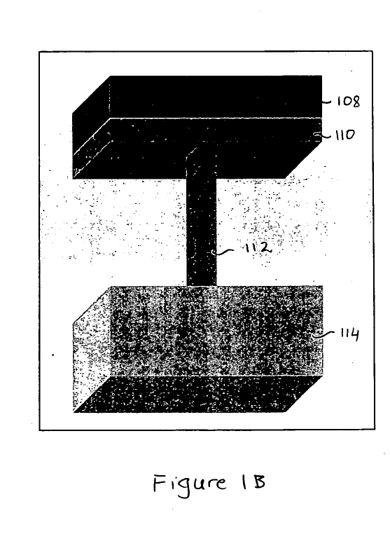

FIG. 1A and FIG. 1B illustrate memory cores in accordance with an embodiment of the present invention. The memory core in FIG. 1A includes a top electrode 102 and a bottom electrode 106 and a threshold-switching layer 104 disposed between the top electrode and the bottom electrode. The top electrode 106 may be a metal, metalloid, semiconductor, or silicide, or a silicon material. The threshold-switching layer 104 may be made of chalcogenide, amorphous silicon, or any material having stable and tunable voltage threshold properties. The bottom electrode 106 may be a metal, metalloid, semiconductor, or silicide, or silicon or other material having stable and tunable voltage threshold properties.

Similarly, FIG. 1B illustrates another embodiment of the memory core. In this embodiment the memory core includes a top electrode 108 and a bottom electrode 112 and a threshold-switching layer 110 disposed between the top electrode and a first end of the bottom electrode 112. The first end of the bottom electrode 112 is in communication with threshold-switching layer 110 and the second end of the bottom electrode 112 is in communication with the selecting circuits 114. The selecting circuits select the bit line and word line corresponding to a memory cell.

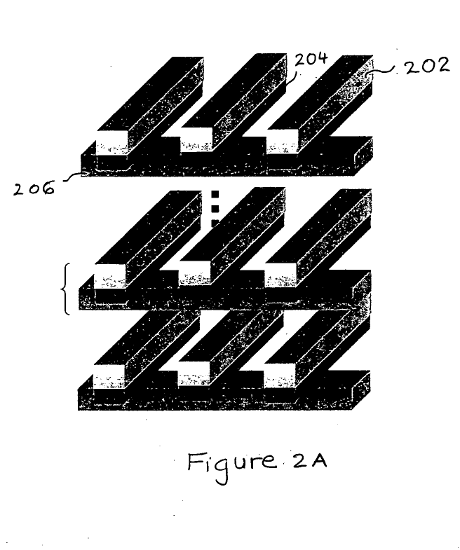

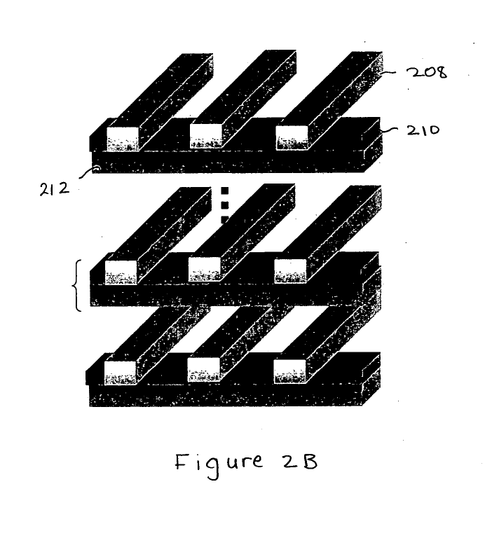

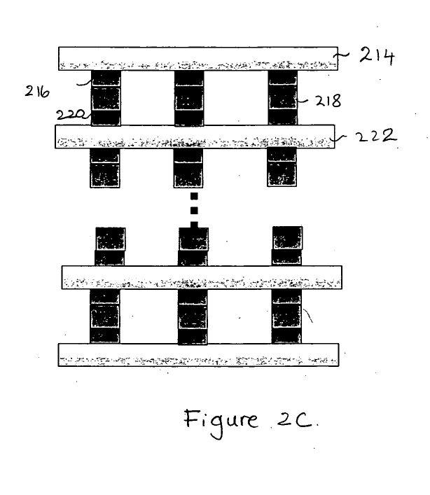

FIG. 2A and FIG. 2B illustrate a stacking memory core of the kind illustrated in FIGS. 1A and 1B to form a memory device. FIG. 2A includes a word line 202 and a bit line 206. It should be understood that in some embodiments 206 may be the word line and 202 the bit line. The Figure further includes a threshold-switching layer 204 disposed between the word line 202 and the bit line 206. The word line 202 and the bit line 204 may be electrodes similar to the electrodes described in FIGS. 1A and 1B. Each memory core may be stacked one on top of the other to make a memory device.

FIG. 2B is similar to FIG. 2A except that the individual layers that make up the memory core are arranged differently. In this embodiment, the memory core includes a bit line 208 and a word line 210. It should be understood that in some embodiments 208 may be the word line and 210 the bit line. The threshold-switching layer 212 lies beneath the word line 210. Thus, each layer that is being stacked includes a bit line 208 word line 210 and a threshold-switching layer 212.

FIG. 2C shows a cross section of a 3D memory fabricated by stacking memory cores similar to the kind of memory cores described in FIG. 2A and FIG. 2B. FIG. 2C includes a word line 214 and bit line 218. FIG. 2C further includes threshold-switching layer 216 disposed between word line 214 and bit line 218. Similarly, another threshold-switching layer 220 is disposed between the bit line 218 and word line 222.

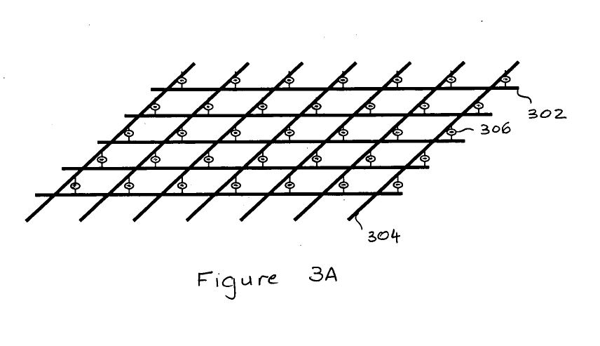

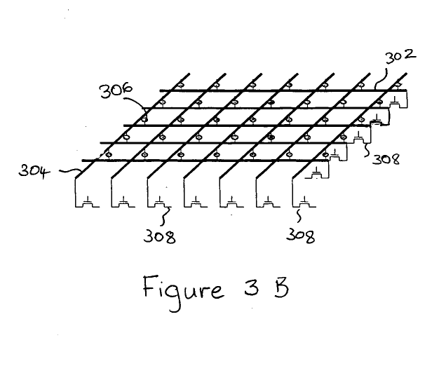

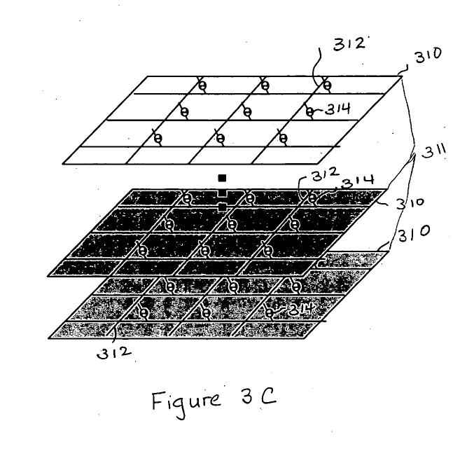

A 3 D memory may be fabricated by stacking an array of memory cores of the kind described above. FIG. 3A shows an array of memory cores of the type described above with reference to FIGS. 2A and 2B. The array of memory cores may be stacked to form a 3D memory. Each individual memory core, within the array of memory cores, includes a bit line 302, a word line 304, and a threshold-switching layer 306 disposed between the word line and the bit line.

FIG. 3B shows an alternative array of memory cores similar to the array described in FIG. 3A. In this embodiment of the invention, word line and bit line select devices 308 are connected at the periphery of the array of memory cores. Even though FIG. 3B shows the select-devices 308 to be transistors, it is understood that the select devices can also be P-N diodes, Schottky diodes, or tunneling diodes. FIG. 3C illustrates a schematic of a multilayered three-dimensional memory. The Figure includes a plurality of memory array layers 311. Each layer 311 includes a plurality of word lines 310, bit lines 312, and threshold-switching layer 314. FIG. 3D illustrates that three dimensional memory may be fabricated by stacking an array of memory cores in accordance with an embodiment of the invention. Each of the memory core array 317 includes a plurality bit lines 316, a plurality of word lines 318 and threshold-switching layers 320 disposed between the bit lines 316 and the word lines 318.

In the present invention, the memory core is serving both as a steering element and a memory element, thus avoiding the use of transistors as steering elements. As explained above, omission of transistors as steering elements virtually eliminates the need for the use of high quality silicon for the fabrication of the memory. Also, the temperature required for the memory fabrication is fairly low. Furthermore, multi-layers may be fabricated through conventional photo/etching or a damascene process without requiring any alignment between layers.

As the threshold-switching material is used for steering, the need for extra steering elements is eliminated. Consequently, memory core arrays can be manufactured layer by layer which may be easily integrated into a 3D memory. This aids in increasing the memory density by incorporating multiple layers.

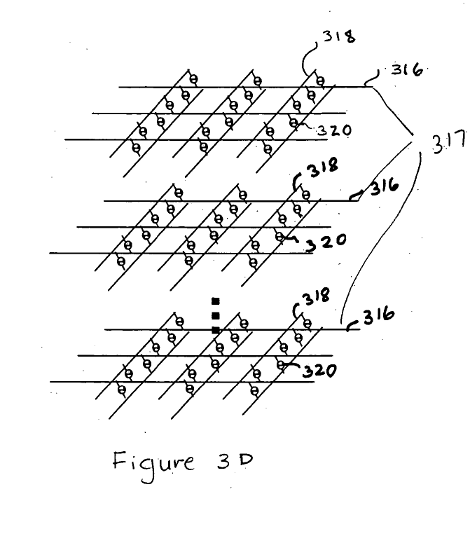

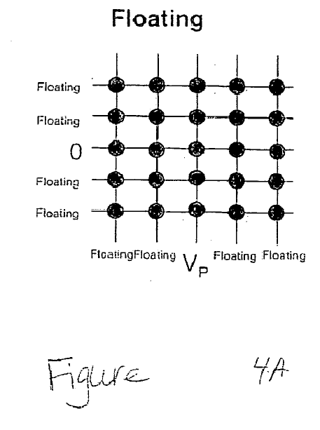

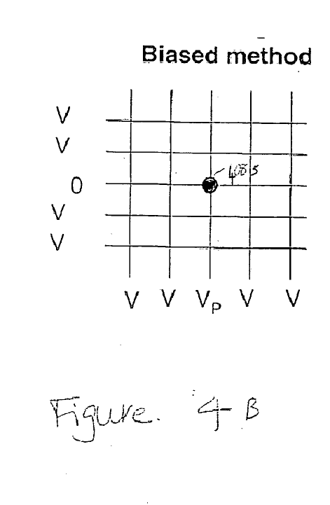

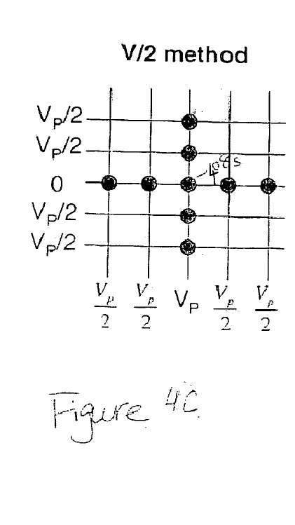

FIGS. 4A through 4D illustrate exemplary plots associated with programming techniques that may be applied to a chalcogenide device. FIG. 4A illustrates a floating programming technique. Here, it is assumed that the chalcogenide memory device includes two voltage thresholds, i.e., a low voltage threshold (Vth) as state 1 and a high voltage threshold (Vₜₕₕ) state 0. The plot of FIG. 4A illustrates the bias applied and the resulting bias on the cells. The unselected cells are associated with a bias of −VP to +VP. The selected cell is associated with a forward bias of +Vp. Cell 408s represents the selected cell, while the remainder of cells 408a-408n represent the unselected cells. Table 1 below summarizes the programming method for program 1 and program 0.

TABLE 1

| | Program 1 | Program 0 |
|---|---|---|
| Selected Bit line | 0 | 0 |
| Other Bit line | Floating | Floating |
| Selected Word line | Vₚₗ | Vₚₕ |
| Other Word line | Floating | Floating |

As summarized in Table 1, the selected bit line is zero, while the selected word line is dependent upon the program or state selected, i.e., Vₚ₁ or Vₚₕ.

FIG. 4B illustrates a biased programming technique. The plot of FIG. 4B illustrates the bias applied. Here, a voltage (bias) may be applied on the unselected word lines and bit lines. The selected cell 408s is associated with a forward bias of +Vₚ. It may be assumed that the chalcogenide memory device includes two voltage thresholds, i.e., a low voltage threshold (Vₜₕ₁) as state 1 and a high voltage threshold (Vₜₕₕ) as state 0. The programming method for states 1 and 0 is listed in Table 2 below.

TABLE 2

| | Program 1 | Program 0 |
|---|---|---|
| Selected Bit line | 0 | 0 |
| Other Bit line | 0 ≦ V ≦ Vₚₗ | 0 ≦ V ≦ Vₚₕ |
| Selected Word line | Vₚₗ | Vₚₕ |
| Other Word line | 0 ≦ V ≦ Vₚₗ | 0 ≦ V ≦ Vₚₕ |

As summarized in Table 2, the selected bit line is zero, while the selected word line is dependent upon the program or state selected, i.e., Vₚ₁ or Vₚₕ. It should be appreciated that two exemplary types of bias programming methods may be used, i.e., the V/2 method and the V/3 method, illustrated in FIGS. 4C and 4D, respectively. Of course, other bias programming methods may be used as the programming methods illustrated herein are exemplary and not meant to be limiting.

FIG. 4C illustrates a plot of the V/2 method. The plot of FIG. 4C illustrates the bias applied and the resulting bias on the cell. The selected cell 408s is associated with a forward bias of +Vₚ while the remaining unselected cells are associated with a forward bias of +Vₚ/2. It may be assumed that the chalcogenide memory device includes two voltage thresholds, i.e., a low voltage threshold (VthI) as state 1 and a high voltage threshold (Vthh) state 0. The programming method for states 1 and 0 is listed in Table 3 below.

TABLE 3

| | Program 1 | Program 0 |
|---|---|---|
| Selected Bit line | 0 | 0 |
| Other Bit line | Vₚₗ/2 | Vₚₕ/2 |
| Selected Word line | Vₚₗ | Vₚₕ |
| Other Word line | Vₚₗ/2 | Vₚₕ/2 |

As summarized in Table 3, the selected bit line is zero, while the selected word line is dependent upon the program or state selected, i.e., Vₚ₁ or Vₚₕ.

FIG. 4D illustrates a plot of the V/3 method. The plot of FIG. 4D illustrates the bias applied and the resulting bias on the cell. The selected cell 408s is associated with a forward bias of +Vₚ while the remaining unselected cells fall into one of two characterizations, i.e., those associated with a forward bias and those associated with a reverse bias. Cells 408f are associated with a forward bias of +Vₚ/3, while cells 408r are associated with a reverse bias of −Vₚ/3. It may be assumed that the chalcogenide memory device includes two voltage thresholds, i.e., a low voltage threshold (Vₜₕ₁) as state 1 and a high voltage threshold (Vₜₕₕ) state 0. The programming method for states 1 and 0 is listed in Table 4 below.

TABLE 4

| | Program 1 | Program 0 |
|---|---|---|
| Selected Bit line | 0 | 0 |
| Other Bit line | 2Vₚₗ/3 | 2Vₚₕ/3 |
| Selected Word line | Vₚₗ | Vₚₕ |
| Other Word line | Vₚₗ/3 | Vₚₕ/3 |

As summarized in Table 4, the selected bit line is zero, while the selected word line is dependent upon the program or state selected, i.e., Vₚ₁ or Vₚₕ. It should be appreciated that the limit of the programming voltage may be represented as: Vₜₕ high <Vₚ<3Vₜₕ low.

The reading methods include a floating method and a bias method. The floating method refers to a bias Vᵣ that is applied between Vₜₕ₁ and Vₜₕₕ on the selected word line (or bit line) and zero bias on the selected word line (or bit line). Other word lines and bit lines are floating. The bias method refers to a bias Vᵣ that is applied between Vₜₕ₁ and Vₜₕₕ on the selected word line (or bit line) and zero bias on the selected word line (or bit line). Other word lines and bit lines apply a certain bias of 0<V<Vₜₕ₁. Two illustrative bias methods, V/2 method and V/3 method were presented.

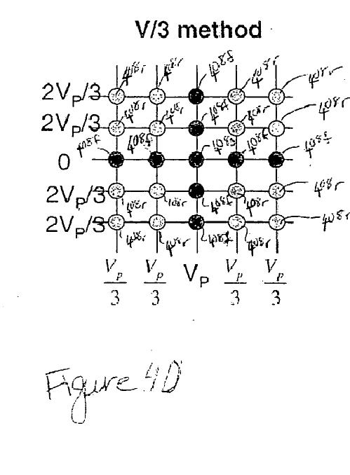

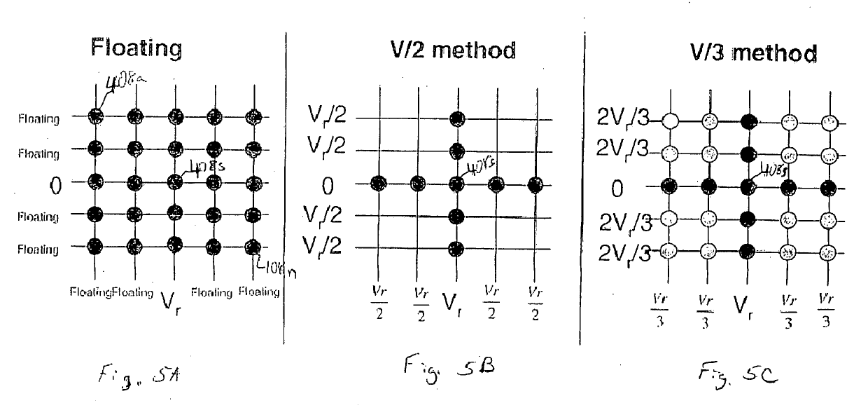

FIGS. 5A through 5C illustrate three exemplary methods for reading a device. Each of FIGS. 5A-5C represents the bias applied and the resulting bias on the cells. FIG. 5A represents a floating method where the bias is −Vᵣ to +Vᵣ and selected cell 408s is associated with a forward bias of +Vᵣ. FIG. 5B represents a V/2 reading method. Selected cell 408s is associated with a forward bias of +Vᵣ. The remaining unselected cells of FIG. 5B are associated with a forward bias of +Vᵣ/2. FIG. 5C represents a V/3 reading method. Selected cell 408s is associated with a forward bias of +Vᵣ. The remaining unselected cells of FIG. 5C are associated with either a forward bias of +Vᵣ/3 or a reverse bias of −Vᵣ/3. It should be appreciated that the unselected cells for FIG. 5C form a similar pattern as discussed above with reference to FIG. 4D.

In summary, the present invention provides a memory core that eliminates the need for access transistors providing access to the core cells. That is, the access to the core cells may be accomplished through the programming of the core cells when the core cells incorporate a threshold-switching material, e.g., a chalcogenide material. In essence, the steering element is now accomplished through the programming of the threshold-switching material. One skilled in the art will appreciate that the elimination of the access transistors also provides for simplified decode logic as signals for the access transistors are no longer necessary for the embodiments described herein.

The invention has been described herein in terms of several exemplary embodiments. Other embodiments of the invention will be apparent to those skilled in the art from consideration of the specification and practice of the invention. The embodiments and preferred features described above should be considered exemplary, with the scope of the invention being defined by the appended claims and their equivalents.

1. A memory core, comprising:
a top electrode;
a bottom electrode; and
a threshold-switching material disposed between the top electrode and the bottom electrode, wherein the threshold-switching material serves as both a steering element and a storage element.

2. The memory core of claim 1, wherein the threshold-switching material is configured to provide a nonvolatile memory.

3. The memory core of claim 1, wherein the threshold-switching material is a chalcogenide material.

4. The memory core of claim 1, wherein the top electrode is a word line and the bottom electrode is a bit line.

5. The memory core of claim 1, wherein the top electrode is a bit line and the bottom electrode is a word line.

6. The memory core of claim 1, wherein the top electrode is composed of one of a metal or a metalloid.

7. The memory core of claim 1, wherein the bottom electrode is selected from a group consisting of semiconductor, silicide, and silicon.

8. The memory core of claim 1, wherein the threshold-switching material is programmed by one of a floating technique or a bias technique.

9. The memory core of claim 8 wherein the floating technique is associated with zero bias on a selected bit line and a voltage from about 0.1V to about 20 V on a selected word line while unselected bit lines and word lines are floating.

10. The memory core of claim 9, wherein the bias technique is associated with a zero bias on a selected bit line and a voltage from about 0.1V to about 20V on a selected word line, while applying a bias between 0 V and about 20V on unselected bit lines and word lines, such that the threshold-switching layer is in a conducting state.

11. A 3 dimensional (3D) memory comprising, a plurality of array of memory cores, wherein each memory core comprising:
a word line;
a bit line; and
a threshold-switching layer disposed between the word line and the bit line.

12. The 3D memory of claim 11, wherein the threshold-switching layer is configured to provide a nonvolatile memory.

13. The 3D memory of claim 11, wherein the 3D memory is further configured to act as a steering device and a storage device.

14. The 3D memory of claim 12, wherein the threshold-switching material is programmed by one of a floating technique and a bias technique.

15. The 3D memory of claim 12, wherein the threshold-switching material is read by one of a floating technique and a bias technique.

16. A method for accessing a memory core in a 3D memory, comprising:
determining a threshold voltage for access to a memory core;
programming a threshold-switching material of the memory core cell to enable access to the memory core at the threshold voltage;
applying a voltage to a word line in communication with the memory core; and
if the voltage is at least as large as the threshold voltage, accessing the memory core.

17. The method of claim 16, wherein the programming of a threshold-switching material of the memory core to enable access to the memory core cell at the threshold voltage includes:
applying one of a floating technique or a bias technique.

18. The method of claim 16, further comprising:
if the voltage is less than the threshold voltage, denying access to the memory core.

19. The method of claim 16, wherein the threshold-switching material is a chalcogenide material.

20. A method for reading a chalcogenide 3D chalcogenide memory device comprising:
applying a read voltage to a selected word line, the read voltage configured to directly access the chalcogenide memory device;
applying a zero bias on a bit line corresponding to the selected word line; and
reading a value stored in the chalcogenide memory device.

21. The method of claim 20, further comprising:
maintaining both unselected word lines and unselected bit lines in a floating state.

22. The method of claim 20, further comprising:
applying a bias voltage to both unselected word lines and unselected bit lines.

23. The method of claim 22, wherein the bias voltage is less than a threshold voltage in the range from about 0.1V to about 20V.

24. The method of claim 22, wherein the bias voltage is one of about one half of the read voltage.

25. The method of claim 22, wherein the bias voltage is about one third of the read voltage on the unselected word lines and about two third of the read voltage on the unselected bit lines.
